(19) United States
(12) Patent Application Publication
(10) Pub. No.: US 2018/0076788 A1
(43) Pub. Date: Mar. 15, 2018

(54) IMPEDANCE MATCHING NETWORK USING HEAT PIPE INDUCTOR

(71) Applicant: Reno Technologies, Inc., Wilmington, DE (US)

(72) Inventors: Ronald Anthony Decker, Turnersville, NJ (US); Dwight Jonathan Tucci, Philadelphia, PA (US); Michael Gilliam Ulrich, Delran, NJ (US)

(21) Appl. No.: 15/816,351

(22) Filed: Nov. 17, 2017

Related U.S. Application Data
(63) Continuation-in-part of application No. 15/450,495, filed on Mar. 6, 2017.
Application No. 15/450,495 is a continuation-in-part of application No. 15/196,821, filed on Jun. 29, 2016.
(60) Provisional application No. 62/185,998, filed on Jun. 29, 2015.
(60) Provisional application No. 62/303,625, filed on Mar. 4, 2016.
(60) Provisional application No. 62/424,162, filed on Nov. 18, 2016.

(51) Int. Cl. H03H 7/38; H01J 37/32; H05K 7/20; H01F 27/18; H01F 27/28

(52) U.S. Cl. CPC H03H 7/38; H01J 37/32183; H05K 7/20154; H01J 2237/002; H05K 7/20172; H01F 27/18; H01F 27/28; H05K 7/20336

(57) ABSTRACT

In one embodiment, the invention may be an impedance matching network including an input configured to operably couple to a radio frequency source, an output configured to operably couple to a load, and a first variable capacitor. The matching network may further include an inductor formed from a heat pipe that is wound in a three-dimensional shape. A first heat sink may be coupled adjacent to a first end of the heat pipe, and a second heat sink may be coupled adjacent to a second, opposite end of the heat pipe.

### CROSS REFERENCE TO RELATED APPLICATIONS

The present application is a continuation in part of U.S. patent application Ser. No. 15/450,495, filed Mar. 6, 2017, which is a continuation in part of U.S. patent application Ser. No. 15/196,821, filed Jun. 29, 2016, which claims the benefit of U.S. Provisional Patent Application No. 62/185,998 filed on Jun. 29, 2015. U.S. patent application Ser. No. 15/450,495 further claims the benefit of U.S. Provisional Patent Application No. 62/303,625, filed Mar. 4, 2016. The present application further claims the benefit of U.S. Provisional Patent Application No. 62/424,162, filed Nov. 18, 2016. The disclosures of the aforementioned priority applications are incorporated herein by reference in their entirety.

### BACKGROUND

Many high-power radio frequency (RF) applications require inductors that are subject to large amounts of power dissipation. This power dissipation will result in a temperature rise in the inductor. This will cause the inductors to be become lossier, which will increase the amount of power dissipated. This cycle will repeat until the temperature reaches equilibrium. The heating can also change the dimensions of the inductor, due to thermal expansion. The increased loss and the change in dimensions can negatively affect the performance of the inductor and be detrimental to a highly-tuned circuit. Another issue with such heating is that inductors have the potential to reach dangerously high temperatures that can lead to failure before reaching equilibrium, known as thermal runaway. Thus, there is need for an improved solution to high-temperature inductors.

### BRIEF SUMMARY

In one aspect, an impedance matching network includes an input configured to operably couple to a radio frequency (RF) source; an output configured to operably couple to a load; a first variable capacitor; an inductor formed from a heat pipe that is wound in a three-dimensional shape; a first heat sink coupled adjacent to a first end of the heat pipe; and a second heat sink coupled adjacent to a second, opposite end of the heat pipe.

In another aspect, a method of cooling an impedance matching network includes coupling an inductor to the matching network, the inductor formed from a heat pipe that is wound in a three-dimensional shape; coupling a first heat sink to a first end of the heat pipe; and coupling a second heat sink to a second, opposite end of the heat pipe.

In another aspect, a method of manufacturing a semiconductor includes operably coupling a matching network between an RF source and a plasma chamber, the plasma chamber configured to deposit a material layer onto the substrate or etch a material layer from the substrate, and the matching network comprising an input configured to operably couple to the RF source; an output configured to operably couple to the plasma chamber; a first variable capacitor; an inductor formed from a heat pipe that is wound in a three-dimensional shape; a first heat sink coupled adjacent to a first end of the heat pipe; and a second heat sink coupled adjacent to a second, opposite end of the heat pipe; placing a substrate in the plasma chamber; energizing plasma within the plasma chamber by coupling RF power from the RF source into the plasma chamber to perform a deposition or etching; and controlling a capacitance of the first variable capacitor to achieve an impedance match.

In another aspect, an electronic device includes an inductor formed from a heat pipe that is wound in a three-dimensional shape; a first heat sink coupled adjacent to a first end of the heat pipe; and a second heat sink coupled adjacent to a second, opposite end of the heat pipe.

### BRIEF DESCRIPTION OF THE DRAWINGS

The present disclosure will become more fully understood from the detailed description and the accompanying drawings, wherein:

FIG. 1 is a system incorporating a pi matching network according to one embodiment.

FIG. 2 is a T matching network according to one embodiment.

FIG. 3 is an L matching network according to one embodiment.

FIG. 4 is a T-variation matching network according to one embodiment.

FIG. 5 is a pi-variation matching network according to one embodiment.

FIG. 6 is an impedance Smith chart for the pi matching network of FIG. 1 where capacitor C3 is omitted.

FIG. 7 is an impedance Smith chart for the pi matching network of FIG. 1 where C3=C2_{Max}.

FIG. 8 is an impedance Smith chart for the pi matching network of FIG. 1 where C3=C2_{Min}.

FIG. 9 is an impedance Smith chart for the pi matching network of FIG. 1 where C3 is replaced with a variable capacitor.

FIG. 10 is matching network using transmission lines to rotate the impedance.

FIG. 11 is a flowchart of a method of manufacturing a semiconductor according to one embodiment.

FIG. 12 is a graph of capacitance for an accumulative EVC according to one embodiment.

FIG. 13 is a graph of a capacitance for a binary weighted EVC according to one embodiment.

FIG. 14 is a graph of current versus current rating according to one embodiment.

FIG. 15 is a graph of a capacitance for a binary with overlap EVC according to one embodiment.

FIG. 16 is a schematic of a variable capacitance system according to one embodiment.

FIG. 17 is a graph of a capacitance of a partial binary EVC according to one embodiment.

FIG. 18 is a flow chart of a method for varying capacitance according to one embodiment.

FIG. 19 is a block diagram a portion of a matching network that incorporates a heat pipe inductor according to one embodiment.

FIG. 20 is a perspective view of an electronic device comprising a heat pipe inductor according to one embodiment.

FIGS. 21-23 are surface temperature plots for simulations of heat distribution in a solid copper pipe inductive device, a cobber tube inductive device, and a heat pipe inductive device, respectively, according to one embodiment.

FIG. 24 is a graph of inductor internal temperatures for the simulations of FIGS. 21-23.

FIG. 25 is a flow chart of a method for cooling an impedance matching network according to one embodiment.

### DETAILED DESCRIPTION

The following description of the preferred embodiment(s) is merely exemplary in nature and is in no way intended to limit the invention or inventions. The description of illustrative embodiments is intended to be read in connection with the accompanying drawings, which are to be considered part of the entire written description. In the description of the exemplary embodiments disclosed herein, any reference to direction or orientation is merely intended for convenience of description and is not intended in any way to limit the scope of the present invention. The discussion herein describes and illustrates some possible non-limiting combinations of features that may exist alone or in other combinations of features. Furthermore, as used herein, the term “or” is to be interpreted as a logical operator that results in true whenever one or more of its operands are true. Furthermore, as used herein, the phrase “based on” is to be interpreted as meaning “based at least in part on,” and therefore is not limited to an interpretation of “based entirely on.”

Features of the present invention may be implemented in software, hardware, firmware, or combinations thereof. The computer programs described herein are not limited to any particular embodiment, and may be implemented in an operating system, application program, foreground or background processes, driver, or any combination thereof. The computer programs may be executed on a single computer or server processor or multiple computer or server processors.

Processors described herein may be any central processing unit (CPU), microprocessor, micro-controller, computational, or programmable device or circuit configured for executing computer program instructions (e.g., code). Various processors may be embodied in computer and/or server hardware of any suitable type (e.g., desktop, laptop, notebook, tablets, cellular phones, etc.) and may include all the usual ancillary components necessary to form a functional data processing device including without limitation a bus, software and data storage such as volatile and non-volatile memory, input/output devices, graphical user interfaces (GUIs), removable data storage, and wired and/or wireless communication interface devices including Wi-Fi, Bluetooth, LAN, etc.

Computer-executable instructions or programs (e.g., software or code) and data described herein may be programmed into and tangibly embodied in a non-transitory computer-readable medium that is accessible to and retrievable by a respective processor as described herein which configures and directs the processor to perform the desired functions and processes by executing the instructions encoded in the medium. A device embodying a programmable processor configured to such non-transitory computer-executable instructions or programs may be referred to as a “programmable device”, or “device”, and multiple programmable devices in mutual communication may be referred to as a “programmable system.” It should be noted that non-transitory “computer-readable medium” as described herein may include, without limitation, any suitable volatile or non-volatile memory including random access memory (RAM) and various types thereof, read-only memory (ROM) and various types thereof, USB flash memory, and magnetic or optical data storage devices (e.g., internal/external hard disks, floppy discs, magnetic tape CD-ROM, DVD-ROM, optical disk, ZIP™ drive, Blu-ray disk, and others), which may be written to and/or read by a processor operably connected to the medium.

In certain embodiments, the present invention may be embodied in the form of computer-implemented processes and apparatuses such as processor-based data processing and communication systems or computer systems for practicing those processes. The present invention may also be embodied in the form of software or computer program code embodied in a non-transitory computer-readable storage medium, which when loaded into and executed by the data processing and communications systems or computer systems, the computer program code segments configure the processor to create specific logic circuits configured for implementing the processes.

Ranges are used as shorthand for describing each and every value that is within the range. Any value within the range can be selected as the terminus of the range. In addition, all references cited herein are hereby incorporated by referenced in their entireties. In the event of a conflict in a definition in the present disclosure and that of a cited reference, the present disclosure controls.

In the following description, where circuits are shown and described, one of skill in the art will recognize that, for the sake of clarity, not all peripheral circuits or components are shown in the figures or described in the description.

### Voltage Reduction Circuit

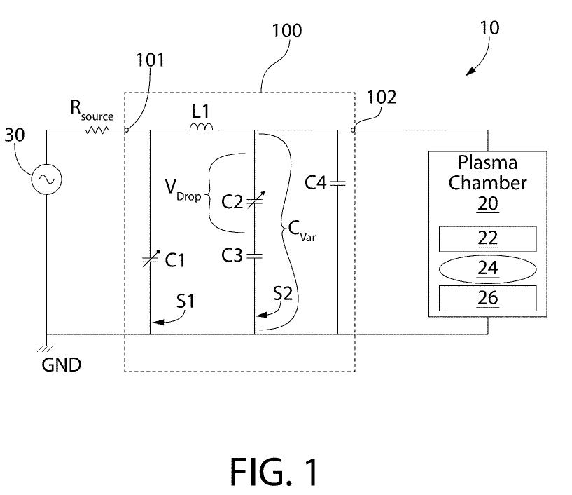

Referring now to FIG. 1, a system 10 incorporating a pi matching network 100 according to one embodiment is shown. In this embodiment, the system 10 is a system for manufacturing semiconductors. In other embodiments, the matching network can form part of any system attempting to match a source impedance to a load impedance to maximize power transfer to the load.

In the exemplified embodiment, the system 10 includes a radio frequency (RF) source 30 having a substantially fixed output impedance R_{source} (e.g., 50 ohms). The RF source 30 generates an RF signal that is received at the input 101 of the matching network 100. The RF source 30 is also operably coupled to chassis ground GND. The RF source 30 may be an RF generator of a type that is well-known in the art to generate an RF signal at an appropriate frequency and power for the process performed within the load 20. The RF source 30 may be electrically connected to the RF input 101 of the impedance matching network 100 using a coaxial cable or similar means, which for impedance matching purposes may have the same fixed (or substantially fixed) impedance as the RF source 30.

The system 10 further includes a load. In the exemplified embodiment, the load is a plasma chamber 20 for manufacturing a semiconductor. The semiconductor device can be a microprocessor, a memory chip, or another type of integrated circuit or device.

As is known in the art, the plasma within a plasma chamber 20 typically undergoes certain fluctuations outside of operational control so that the impedance presented by the plasma chamber 20 is a variable impedance. Since the variable impedance of the plasma chamber 20 cannot be fully controlled, an impedance matching network may be used to create an impedance match between the plasma chamber 20 and the RF source 30. In other embodiments, the load can be any load of variable impedance that can utilize a matching network.

The plasma chamber 20 can include a first electrode 22 and a second electrode 26, and in processes that are well known in the art, the first and second electrodes, in conjunction with appropriate control systems (not shown) and the plasma in the plasma chamber 120, enable one or both of deposition of materials onto a substrate 24 and etching of materials from the substrate 24. The plasma chamber 20 can receive an RF signal from the output 102 of the matching network 100 and thereby receive RF power from the RF source 30 to energize plasma within the plasma chamber 20 to perform the deposition or etching.

The matching network 100 can consist of a single module within a single housing designed for electrical connection to the RF source 30 and plasma chamber 20. In other embodiments, the components of the matching network 100 can be located in different housings, some components can be outside of the housing, and/or some components can share a housing with a component outside the matching network 100.

The matching network 100 provides impedance matching for the RF source 30 and the plasma chamber 20. The matching network 100 is operably coupled between the RF source 30 and the plasma chamber 20. The matching network 100 includes an input 101 configured to operably couple to the RF source 30, and an output 102 configured to operably couple to the plasma chamber 20. The matching network 100 further includes a first variable capacitor C1 and a second variable capacitor C2. In a preferred embodiment, the variable capacitors C1, C2 are EVCs, though in other embodiments, other types of variable capacitors can be used, such as VVCs.

In this first embodiment, the matching network 100 is a pi network. The first variable capacitor C1 forms part of a first shunt S1 parallel to the RF source 30, and the second variable capacitor C2 forms part of a second shunt S2 separate from the first shunt S1. Put differently, the first variable capacitor C1 is parallel to the input 101, and the second variable capacitor C2 is parallel to the output 102. Further, a first inductor L1 is located between the first shunt S1 and the second shunt S2. In other embodiments, a second inductor L2 can be located between the second shunt S2 and the output 102.

The first variable capacitor C1 has a first capacitance, and the second variable capacitor C2 has a second capacitance. The first capacitance and the second capacitance are configured to be altered to create an impedance match at the input. As will be discussed further herein, however, the invention is not limited to pi matching networks, as other types of matching networks can be utilized.

To reduce a voltage on the second variable capacitor C2, the matching network 100 further includes a third capacitor C3 in series with the second variable capacitor C2. Components or nodes are said to be “in series” if the same current flows through each. In the exemplified embodiment, the third capacitor C3 forms part of the second shunt S2, though the invention is not so limited. In other embodiments, the third capacitor C3 can be at different locations, provided the third capacitor C3 is positioned to reduce a voltage on the second variable capacitor C2 (the reduced voltage being, for example, an alternating current or radio frequency voltage). For example, the positions of C2 and C3 in FIG. 1 can be reversed. Alternative embodiments are discussed below. In the embodiments discussed, the third or additional capacitor is a non-variable capacitor, though in other embodiments a variable capacitor can be used.

In the exemplified embodiment, a fourth capacitor C4 is included. The fourth capacitor C4 is parallel to the second shunt S2 and helps to offset the total capacitance. In other embodiments, the fourth capacitor C4 can be omitted.

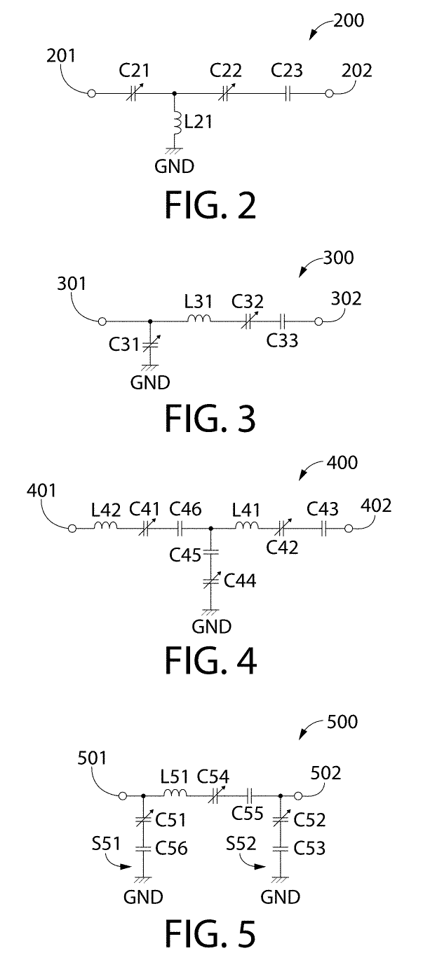

FIG. 2 is a T matching network 200 according to a second embodiment. The matching network 200 includes an input 201 configured to operably couple to an RF source and an output 202 configured to operably couple to a load. A first variable capacitor C21 is in series with the input 201, and a second variable capacitor C22 is in series with the output 202. An inductor L21 at one end is coupled at a node between the two variable capacitors C21, C22 and coupled at another end to chassis ground. As with the first embodiment, the third capacitor C23 is in series with the second variable capacitor C22 to reduce a voltage on the second variable capacitor C22.

FIG. 3 is an L matching network 300 according to a third embodiment. The matching network 300 includes an input 301 configured to operably couple to an RF source and an output 302 configured to operably couple to a load. A first variable capacitor C31 is parallel to the input 301. Further, a second variable capacitor C32 is in series with the output 302. Further, an inductor L31 is in series with the output 302. As with the first embodiment, the third capacitor C33 is in series with the second variable capacitor C32 to reduce a voltage on the second variable capacitor C32.

FIG. 4 is a matching network 400 that is a variation on a T matching network according to a fourth embodiment. The matching network 400 includes an input 401 configured to operably couple to an RF source and an output 402 configured to operably couple to a load. A first variable capacitor C41 is in series with the input 401, a second variable capacitor C42 is in series with the output 202, and another variable capacitor C44 at one end is coupled at a node between the two variable capacitors C41, C42 and coupled at another end to chassis ground. Further, capacitor C46 is in series with capacitor C41, capacitor C43 is in series with capacitor C42, and capacitor C45 is in series with capacitor C44. An inductor L41 is in series with the output 402, and an inductor L42 is in series with the input 401. As with the first embodiment, the third capacitor C43 reduces a voltage on the second variable capacitor C42. Further, capacitors C41 and C45 reduce voltage on capacitors C46 and C44, respectively.

FIG. 5 is a matching network 500 that is a variation on a pi matching network according to a fifth embodiment. The matching network 500 includes an input 501 configured to operably couple to an RF source and an output 502 configured to operably couple to a load. A first variable capacitor C51 forms part of a first shunt S51 parallel to the input 501, a second variable capacitor C52 forms part of a second shunt S52 separate from and parallel to the output 502, and another variable capacitor C54 is located between variable capacitors C51 and C52. Capacitor C56 is in series with variable capacitor C51, capacitor C53 is in series with variable capacitor C52, and capacitor C55 is in series with variable capacitor C54. Further, a first inductor L51 is in series with variable capacitor C54. As with the first embodiment, the third capacitor C53 reduces a voltage on the second variable capacitor C52. Further, capacitors C55 and C56 reduce a voltage on variable capacitors C54 and C51, respectively.

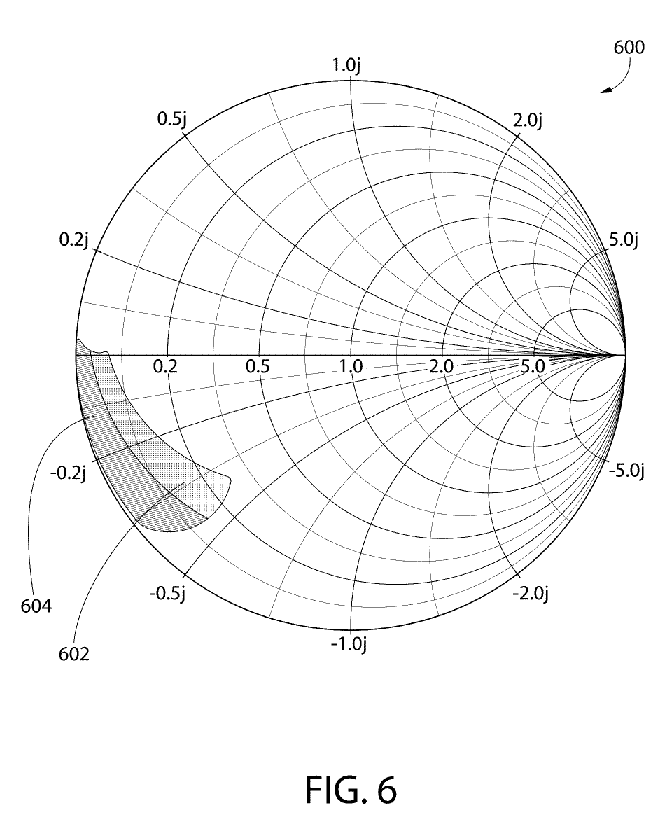

FIG. 6 shows an impedance Smith chart 600 for the matching network of FIG. 1 before the additional capacitor C3 is added. An impedance Smith chart shows the different possible impedances for a matching network. In FIG. 6, the first region 602 and the second region 604 together represent the total number of possible impedances. There is a maximum voltage across C2 (e.g., 1600V). The first region 601 represents the impedance range where the maximum voltage is not exceeded (within spec), and the second region 602 represents the impedance range where the maximum voltage is exceeded (out of spec). It can be seen that about half of the impedance range of the matching network cannot be used at full power due to over voltage.

In the embodiment discussed below, the values of the additional fixed capacitor C3 and variable capacitors C2 (see FIG. 1) are chosen to reduce the voltage V_{Drop} on the variable capacitor C2 by half at the maximum capacitance (compared to the voltage on the variable capacitor C2 without the presence of the additional capacitor C3). This is only an example, and the voltage drop can be altered depending on the application, the desired voltage drop, and/or the availability of components.

The voltage drop V_{Drop} across the variable capacitor C2 (see FIG. 1) can be calculated by the following equation:

$${V}_{Drop} = {V}_{C 2} * \frac{\frac{1}{C 2}}{( \frac{1}{C 2} + \frac{1}{C 3} )}$$

If C2_{Max}=C3, then the formula can be simplified as below, where C2_{Max}=C3=C.

$${V}_{Drop} = {V}_{C 2} * \frac{\frac{1}{C}}{( \frac{1}{C} + \frac{1}{C} )} = {V}_{C 2} * \frac{1}{( 1 + 1 )} = \frac{{V}_{C 2}}{2}$$

As a result, V_{Drop} is equal to half of the voltage that was originally capacitor C2 (V_{C2}) when C3 was not included.

$${V}_{Drop} = \frac{{V}_{C 2}}{2}$$

Continuing with this example, the next step is to find the maximum capacitance required for the variable and fixed capacitors. In this case, the total series capacitance CVar is equal to the maximum capacitance of the original variable capacitor C2. The capacitance CVar can be calculated by the following equation:

$${CVar}_{Max} = {( \frac{1}{C {2}_{Max}} + \frac{1}{C 3} )}^{- 1}$$

If C2_{Max}=C3=C, the equation can be modified as follows:

$$\frac{1}{{CVar}_{Max}} = ( \frac{1}{C} + \frac{1}{C} ) = \frac{2}{C}$$

C is then solved for as follows:

C=2*CVar_{Max}

The minimum value for variable capacitor C2, C2_{Min}, can be found by using the previously calculated value for C3 and replacing the CVar_{Max} with the minimum capacitance, CVar_{Min}, as in the following equations:

$$\frac{1}{C {2}_{Min}} = ( \frac{1}{{CVar}_{Min}} - \frac{1}{C 3} )$$

$$C {2}_{Min} = {( \frac{1}{{CVar}_{Min}} - \frac{1}{C 3} )}^{- 1}$$

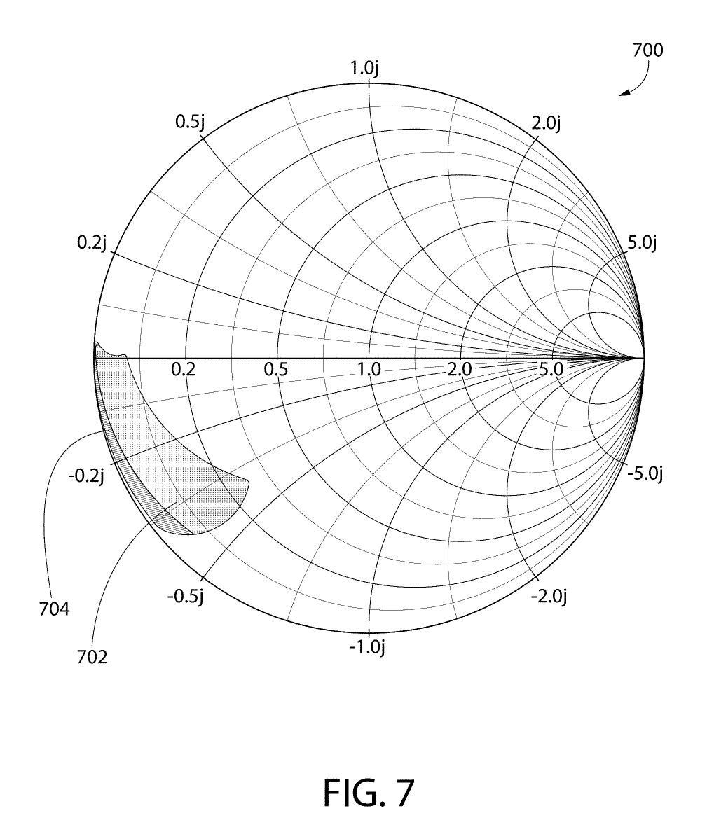

FIG. 7 is an impedance Smith chart 700 where third capacitor C3 is set to the maximum capacitance of second capacitor C2 (C3=C2_{Max}). It is shown that the usable range of the matching network (represented by first region 702) has been increased, and the unusable range (represented by second region 704) has been decreased, without sacrificing the impedance range, using a more expensive, larger, higher voltage component, or adding more peripheral components to meet the voltage requirements.

It can also be seen, however, that the first (usable) region 702 has gaps representing areas where a perfect impedance match is not provided. This can be a result of adding capacitor C3 to reduce the voltage, which increases the gap between the quantized states of the variable capacitor when approaching C2_{Min} and decreased the spacing when approaching C2_{Max}.

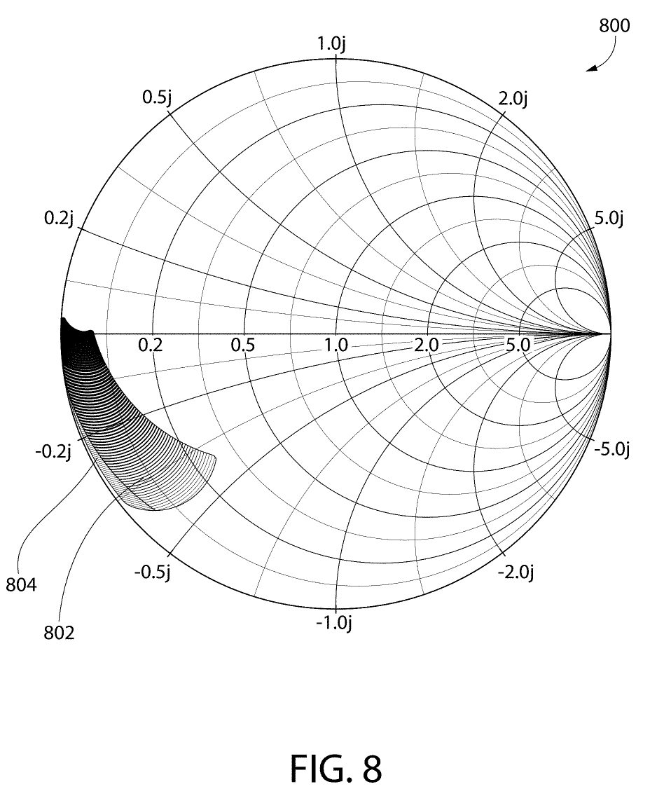

FIG. 8 is an impedance Smith chart 800 where third capacitor C3 is set to the minimum capacitance of second capacitor C2 (C3=C2_{Min}). It is shown that such an arrangement can further increase the usable range (first region 802) of the matching network, and decrease the unusable range (second region 804). C3 can be reduced further, but there is a limit before it affects the maximum capacitance range. To avoid this, each of C3 and C2_{Max} can be greater than CVar_{Max}. This is also true if using two or more variable capacitors in series. Thus, if C1 was replaced with C15 and C16, then C15M, and C16_{Max} can be selected to each be greater than C1_{Max}. C1_{Max} can be calculated using the following equation:

$$C {1}_{Max} = {( \frac{1}{C {15}_{Max}} + \frac{1}{C {16}_{Max}} )}^{- 1}$$

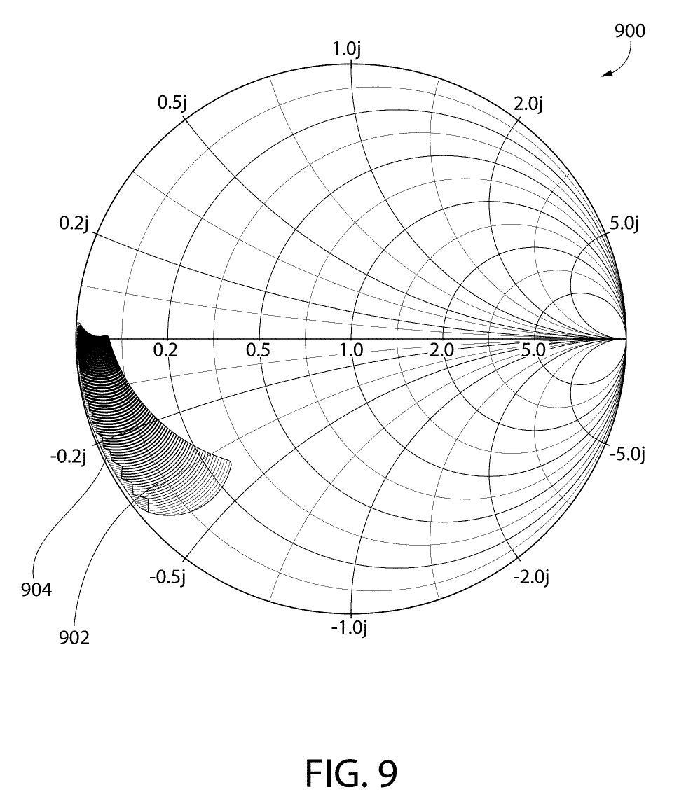

The addition of a third variable or non-variable capacitor, to help further reduce V_{Drop}, can change the capacitor range of the variable capacitor combination C2. To address this, a variable capacitor such as an EVC can be easily modified to adjust the capacitor range. The third capacitor can also change the step sizes and make them nonlinear. In certain embodiments, a more uniform distribution can be provided by using a nonlinear variable capacitor or multiple variable capacitors in series. FIG. 9 is an impedance Smith chart 900 where the third capacitor C3 is replaced with a variable capacitor. This figure shows the usable range (first region 902) of the matching network, and the unusable range (second region 904).

In other embodiments, transmission lines (which can comprise microstrips, coaxial cable, a wave guide, or any other conductive medium) can be used to rotate the impedance of the matching network on the Smith chart. The length of the transmission line at a certain frequency determines the amount of rotation. The longer the transmission line, the more rotation there will be on the Smith chart. A quarter wavelength (λ/4) transmission line (which can be calculated using the operating frequency and the property of the dielectric material) will have a 180° clockwise rotation on the Smith chart, a half wavelength (λ2) transmission line will have a 360° clockwise rotation on the Smith chart, an eighth wavelength (λ/8) would be equal to 45°, and so on.

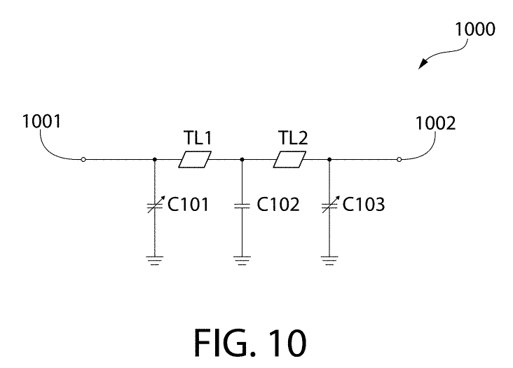

If the matching network 1000 uses only quarter wave lines, or something that would ultimately give a 90° phase shift [(λ/4)+N*(λ/2)], and there are the three capacitors C101, C102, C103 in shunt (together with transmission lines TL1 and TL2), as shown in FIG. 10, the circuit can be equivalent to a low pass pi matching network, with input 1001 and output 1002. Two variable capacitors can be used with a single transmission line between to create the equivalent of an L-type matching network (e.g., C101-TL1-C102 of FIG. 10). Transmission lines can then be added to the input port, the output port or both ports to create the equivalent inverse network of the two previously mentioned matching networks. In other embodiments, other topologies can be created with other transmission lines.

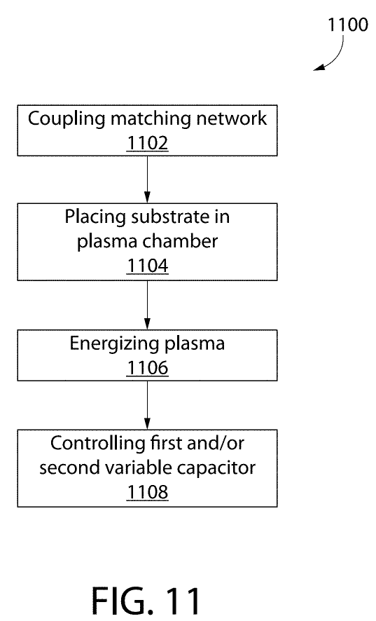

FIG. 11 is a flowchart of a method 1100 of manufacturing a semiconductor according to one embodiment. In the exemplified embodiment, a matching network is operably coupled between an RF source and a plasma chamber (operation 1102), as in the embodiment of the system 10 shown in FIG. 1. The matching network can be configured to have the features of any of the embodiments discussed herein. Further, the method 1100 can include placing a substrate in the plasma chamber (operation 1104). Further, the method 1100 can include energizing plasma within the plasma chamber by coupling RF power from the RF source into the plasma chamber to perform a deposition or etching (operation 1106). Further, the method 1100 can include controlling a capacitance of the first variable capacitor and/or the second variable capacitor to achieve an impedance match (operation 1108).

The foregoing embodiments provide several advantages. The embodiments disclose a matching network that can more effectively handle high voltages generated in a network. Further, the embodiments avoid or minimize the need for increased component sizes (as typically required for a VVC) or increased numbers of peripheral components (as typically required with an EVC). Further, the embodiments provide a solution that has a lower cost than previous methods of addressing high voltages in a matching network. As shown herein, the embodiments can increase the usable range of a matching network without sacrificing the impedance range, using a more expensive, larger, higher voltage component, or adding more peripheral components to meet the voltage requirements.

### Capacitance Variation

As discussed above, an EVC is a type of variable capacitor that can use multiple switches, each used to create an open or short circuit, with individual series capacitors to change the capacitance of the variable capacitor. The switches can be mechanical (such as relays) or solid state (such as PIN diodes, transistors, or other switching devices). The following is a discussion of various methods for setting up an EVC or other variable capacitor to provide varying capacitances.

In an accumulative setup of an EVC, the approach to linearly increase the capacitor value from the minimum starting point (where all switches are open) is to incrementally increase the number of fine tune capacitors that are switched into the circuit. Once the maximum number of fine tune capacitors is switched into circuit, a course tune capacitor is switch in, and the fine tune capacitors are switched out. The process starts over with increasing the number of fine tune capacitors that are switched into circuit, until all fine and course tune capacitors are switched in. In this setup, all of the fine tune capacitors have the same or a substantially similar value, and all the coarse tune capacitors have the same or a substantially similar value. Further, the capacitance value of one course tune capacitor about equals the combined capacitance value of all fine tune capacitors plus an additional fine tune capacitor into the circuit, thus enabling a linear increase in capacitance.

An example of this in an ideal setting would be if the fine tune capacitors were equal to 1 pF, and the course tune capacitors were equal to 10 pF. In this ideal setup, when all switches are open, the capacitance is equal to 0 pF. When the first switch is closed, there is 1 pF in the circuit. When the second switch is closed there is 2 pF in the circuit, and so on, until nine fine tune switches are closed, giving 9 pF. Then, the first 10 pF capacitor is switched into circuit and the nine fine tune switches are opened, giving a total capacitance of 10 pF. The fine tune capacitors are then switched into circuit from 11 pF to 19 pF. Another course tune capacitor can then be switched into circuit and all fine tune capacitors can be switched out of circuit giving 20 pF. This process can be repeated until the desired capacitance is reached.

This can also be taken one step further. Using the previous example, having nine 1 pF capacitors and also nine 10 pF capacitors, the variable capacitor circuit can have even larger values, 100 pF, to switch in and out of circuit. This would allow the previous capacitor array to go up to 99 pF, and then the 100 pF capacitor can be used for the next increment. This can be repeated further using larger increments, and can also be used with any counting system.

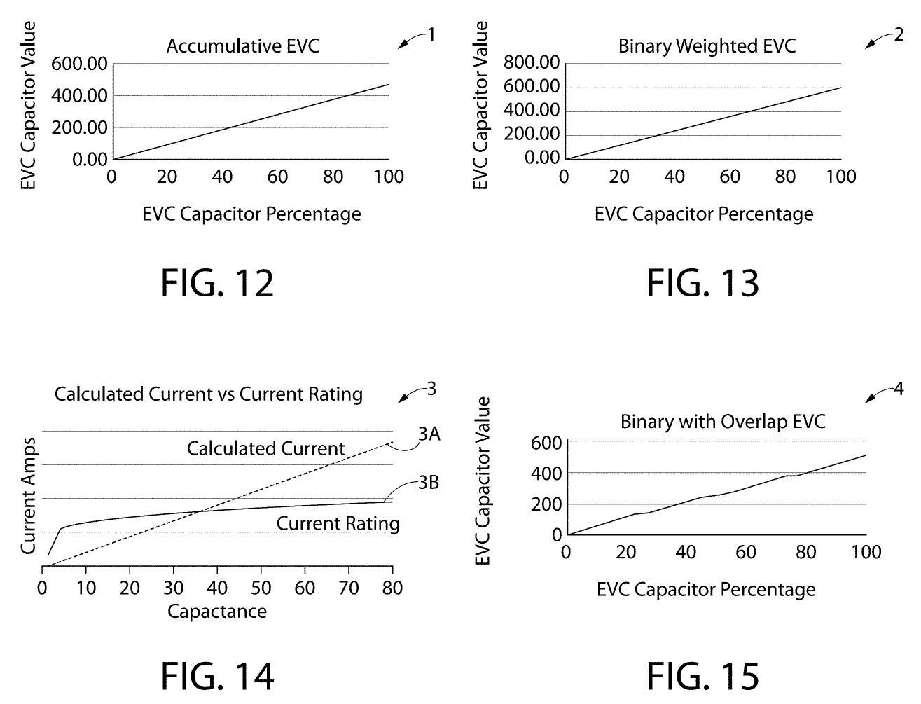

FIG. 12 is a graph 1 of capacitance for an accumulative EVC according to one embodiment. The graph 1 shows the capacitor percentage versus the capacitor value. In this embodiment, there are 12 course tune capacitors, each equal to 36 pF, and 12 fine tune capacitors, each equal to 3.3 pF. The switch is assumed to have a parasitic capacitance of 0.67 pF each. With parasitic capacitance from the switches added in series with each capacitor, the range of the EVC is 14.5 pF (all switches open) to 471.6 pF (all switches closed) and it has 169 unique capacitor values.

An alternative capacitor setup is referred to herein as a binary weighted setup. In the binary weighted setup, the capacitor values will all be different. The first value is equal to the minimum desired change in capacitance. Then each successive capacitor value is increased to double the change in capacitance from the previous up until the maximum desired capacitor value, when all capacitors are switched in.

In one example (that assumes there are no parasitic capacitances), the lowest capacitance capacitor would be a 1 pF capacitor, followed by 2 pF, 4 pF, and so on. When all switches are open, the value is 0 pF. When the 1 pF capacitor is switched in, the EVC total capacitance value is 1 pF. Then the 1 pF capacitor is switched out of circuit and the 2 pF capacitor is switched in, causing a total capacitance of 2 pF. When 3 pF is needed, the 1 pF and the 2 pF capacitors are switched in. For 4 pF, the 1 and 2 pF capacitors are switched out of circuit and the 4 pF capacitor is switched into circuit. This can be repeated adding 1 pF, 2 pF, and 4 pF together in different combinations in the circuit, creating values of 5 pF, 6 pF and 7 pF.

FIG. 13 is a graph 2 of a capacitance for a binary weighted EVC according to one embodiment. As with FIGS. 12 and 14-15, this graph 2 shows the capacitor percentage versus the capacitor value. As used herein, the term “capacitor percentage” refers to the amount of capacitance switched in as a portion of the total potential capacitance. For example, if a binary weighted system has capacitor values 1 pF, 2 pF, and 4 pF, the capacitor percentage would be 0% when all the capacitors are switched out of circuit, and 100% when all the capacitors are switched in. If the 1 pF and 4 pF capacitors are switched in, the capacitor percentage would be 5 pF/7 pF, or 71.4%.

In the embodiment of FIG. 13, the capacitors from lowest to highest value are 3.0 pF, 5.1 pF, 9.1 pF, 18 pF, 36 pF, 75 pF, 150 pF and 300 pF. Again, the switch is assumed to have a parasitic capacitance of 0.67 pF each. With parasitic capacitance from the switches added in series with each capacitor, the capacitors provide a change in capacitance from switch open to switch closed, of 2.45 pF, 4.51 pF, 8.48 pF, 17.4 pF, 35.3 pF, 74.3 pF, 149 pF and 299 pF. The EVC capacitor ranges from 5.04 pF to 596.2 pF, with 256 unique capacitor values.

The binary weighted setup can result in using far less capacitors to switch in and out of circuit to achieve the same or better resolution and range. A potential problem with this setup, however, is that, once the capacitor reaches a certain value, the voltage and/or current on that particular capacitor or the current on the switch can be higher than the specification allows for. This forces the EVC to use multiple capacitors in parallel for each switch of lower value.

FIG. 14 is a graph 3 of current versus current rating according to one embodiment. This graph 3 shows the current 3A against the current ratings 3B of a certain group of capacitors. The increase in current 3A versus the current rating 3B is not proportional and only gets worse as the capacitor value is increased. The capacitors up to 36 pF meet the specification, while the values above do not. In the accumulated method there are no issues, but in the binary weighted method it is better to instead use two 36 pF capacitors in parallel rather than one 75 pF capacitor.

Another potential disadvantage of the binary weighted setup is that it is difficult to achieve a consistent step size throughout the range. The above capacitor values for the binary setup give an average step size of 2.32 pF, compared to the accumulative method, which has an average step size of 2.72 pF. But the minimum and maximum step for the binary weighted setup is 1.51 pF and 7.51 pF, respectively, while the accumulative setup's minimum and maximum are only 2.4 pF and 2.75 pF.

With higher value capacitors, this can be further complicated with finding a value that does not overshoot multiple steps. Also, part-to-part tolerances being greater than the minimum step size can further increase the gaps. A 300 pF capacitor with a ±5% tolerance can have up to 15 pF of extra capacitance. The delta capacitance of the three least significant binary weighted capacitors total 15.44 pF. So, these values are completely overstepped, and linearity is lost.

One modification to the binary weighted setup is to have the larger capacitor values rounded down to the next standard value, for example 3.0 pF, 5.1 pF, 9.1 pF, 18 pF, 36 pF, 68 pF, 130 pF, 240 pF. Doing this would create some overlap in capacitor value where there would be a drop in capacitance when switching in the new larger value and switching out the previous smaller values. For example, the values 3 pF through 36 pF would combine to equal 71.2 pF, but the next step is 68 pF, a drop of 3.2 pF. This problem can be avoided, however, because the EVC does not need to go sequentially through each step, but instead can use software to lookup the next known capacitor position to switch to it directly.

FIG. 15 is a graph 4 of a capacitance for a binary with overlap EVC according to one embodiment. As can be observed, this graph 4 shows how the overlap helps create a smooth increase in capacitance.

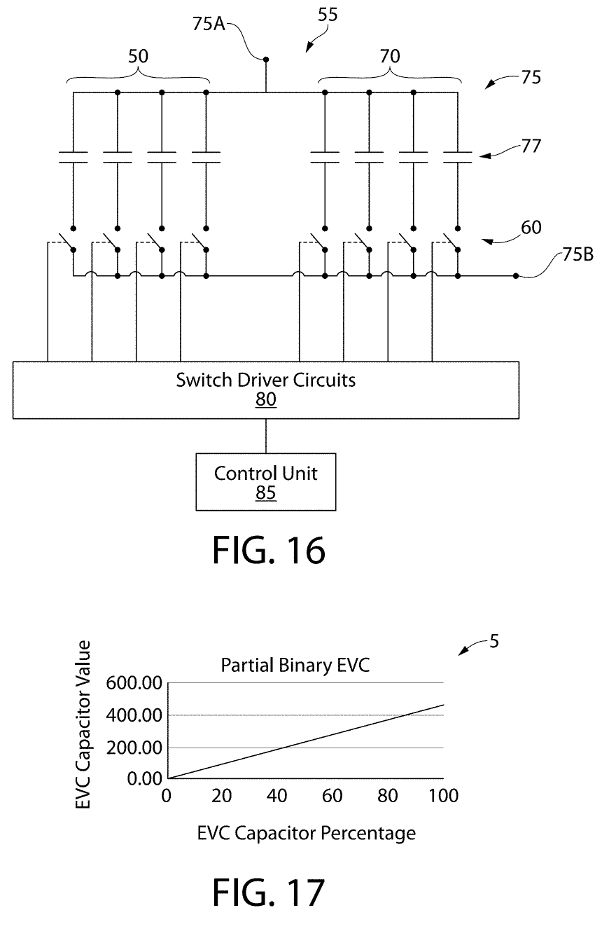

FIG. 16 is a schematic of a variable capacitance system 55 according to a partial binary setup. The partial binary setup uses attributes of both the accumulative and binary setups. The variable capacitance system 55 comprises a variable capacitor 75 (such as an EVC or a VVC) for providing a varying capacitance. The variable capacitor 75 has an input 75A and an output 75B. The variable capacitor 75 includes a plurality of capacitors 77 operably coupled in parallel. The plurality of capacitors 77 includes first capacitors 50 and second capacitors 70. Further, the variable capacitor 75 includes a plurality of switches 60. Of the switches 60, one switch is operably coupled in series to each of the plurality of capacitors to switch in and out each capacitor, thereby enabling the variable capacitor 75 to provide varying total capacitances.

The switches 60 can be coupled to switch driver circuits 80 for driving the switches on and off. The variable capacitance system 55 can further include a control unit 85 operably coupled to the driver circuits 80 for instructing the driver circuits 80 to switch one or more of the switches 60, and thereby turn one or more of the capacitors 77 on or off. In one embodiment, the control unit 85 can form part of a control unit that controls variable capacitor, such as a control unit that instruct the variable capacitors of a matching network to change capacitances to achieve an impedance match.

In the exemplified embodiment, the first capacitors 50 are fine tune capacitors using a method similar to the binary method discussed above. Thus, the fine tune capacitors 50 can have capacitances increasing by a factor of about two, where “about two” refers to a value of 1.5 to 2.5. In an ideal example where there are no parasitic capacitances, the fine tune capacitors could increase by a factor of exactly two (e.g., 1 pF, 2 pF, 4 pF, 8 pF).

But in real world applications, parasitic capacitances, such as those provided by the switches 60, are another factor that must be considered in choosing the capacitance values of the fine tune capacitors 50. Thus, while a first capacitor may have a value of 1 pF, and the corresponding capacitor-switch pair may thus provide 1 pF to a total capacitance of the variable capacitor when the capacitor's corresponding switch is closed, when the switch is open, the open switch may have a parasitic capacitance of, for example, 1 pF. Thus, when the switch is open, there are essentially two 1 pF capacitances in series, which is equivalent to 0.5 pF. Thus, when the first fine tune capacitor switch switches from open to close, the change in the capacitance contributed to the variable capacitor by this capacitor-switch pair is from 0.5 pF (open) to 1 pF (closed), for a change of 0.5 pF. These changes in capacitance caused by parasitic capacitances must be taken into consideration in choosing capacitor values to ensure that the target step size (e.g., 0.5 pF) for the total capacitance can be achieved.

Returning to the previous example, if an EVC had four fine capacitors, and each capacitor switch had a parasitic capacitance of 1 pF, and a step size of 0.5 pF was desired, the fine capacitors could be 1 pF, 1.6 pF, 2.7 pF, and 4.7 pF. As discussed, the first fine capacitor (1 pF) would cause a 0.5 pF change to the total capacitance when switched in. The second fine tune capacitor (1.6 pF) and its switch would provide 0.6 pF when open and 1.6 pF when closed, thus causing a change in the total capacitance of about 1 pF when switched in. The third fine tune capacitor (2.7 pF) would cause a change in the total capacitance of about 2 pF when switched in, and the fourth fine tune capacitor (4.8 pF) would cause a change in the total capacitance of about 4 pF when switched in. Thus, the changes to the total capacitance caused by the switching in of each of the four first tune capacitors would be 0.5 pF, 1 pF, 2 pF, and 4 pF, respectively. Thus, the changes caused by the switching in of each of these capacitors increases by a factor of two. It is understood that the invention is not limited to these values. Other capacitor values (or switches with other parasitic capacitances) can be used such that the changes caused increase by a factor of about two. For example, the 4.8 pF capacitor of the above example could be replaced with a standard 4.7 pF capacitor. Further, other capacitance values can be used to achieve other step sizes. The foregoing considerations regarding parasitic capacitances can equally apply to the binary setup discussed above.

The second capacitors 70, by contrast, are course tune capacitors using a method similar to the accumulative method discussed above. Thus, the second capacitors can have a substantially similar capacitance. Capacitors are considered to have substantially similar capacitances if, of the capacitors in question, no capacitance is 15 percent (15%) greater than or less than another capacitance. Alternatively, the capacitors can be chosen such that there are no gaps in total capacitance greater than the minimum step size needed for the given application.

The first (fine) capacitors 50 can increase their value (or the value by which they change the total capacitance) in a binary fashion, and thus by a factor of about two, up to the first course position. When all of the fine capacitors 50 are switched into circuit, the first course capacitor 71 can be switched in, and all the fine capacitors 50 are switched out. Then the fine capacitors 50 can be switched in and out until they are all switched into circuit. The next step would be to add another course tune capacitor 72. It is understood, however, that the EVC does not need to go sequentially through each step to achieve a desired total capacitance, but instead can use software to lookup the next known capacitor position to switch to it directly.

In one embodiment, there are four fine capacitors 50. The first fine capacitor 51 has a capacitance of 3.0 pF, the second fine capacitor 52 has a capacitance of 5.1 pF, the third fine capacitor 53 has a capacitance of 9.1 pF, and the fourth fine capacitor has a capacitance of 18 pF. Further, there are four course tune capacitors 70 having capacitances of 36 pF each. Thus, in this embodiment, the total combined capacitance of the fine capacitors (35.2 pF) is substantially similar to the individual capacitances of the course capacitors (36 pF). It also follows that the capacitance of each of the course capacitors is greater than a greatest individual capacitance (18 pF) of the fine capacitors.

In this embodiment, there will be 208 unique capacitor values. With parasitics, the minimum total capacitance is 10.25 pF and the maximum total capacitance is 467.2 pF. The range is less than 1 pF less than the accumulative method, but with an increase in unique points. The minimum step size is 1.51 pF, the maximum is 2.54 pF and the average is 2.21 pF. Thus, the results of the setups discussed are as follows:

TABLE 1
Comparison of EVC Setups

| | Accumulative | Binary Weighted | Partial Binary |
|---|---|---|---|
| Min total | 14.5 pF | 5.05 pF | 10.25 pF |
| capacitance | | | |
| Max total | 471.6 pF | 596.2 pF | 467.2 pF |
| capacitance | | | |
| Min and max step | 2.4-2.75 pF | 1.51-7.51 pF | 1.51-2.54 pF |
| size | | | |
| Unique capacitor | 169 | 256 | 208 |
| values | | | |

FIG. 17 is a graph 5 of a capacitance of a partial binary EVC according to one embodiment. The graph shows the capacitor percentage versus the EVC total capacitance for the partial binary method for switching. As can be seen, this setup provides a smooth line for providing the various total capacitances required while also providing a large range.

The partial binary method provides multiple advantages. First, the current on each capacitor will not be over its rating. The maximum current and the current rating will be the same for all course capacitors, because they will be the same value. With the fine steps, all of the capacitor values have a higher ratio of current rating to maximum current. Therefore, no issues should arise.

Further, the partial binary approach avoids large gaps in capacitance steps. Further, less capacitors are needed to have the same range, while the number of unique values can potentially be increased. With less capacitors, the EVC will need less switches, causing the EVC to take up less area. Further, less capacitors will require less hardware to control the switches.

Binary with overlap can also be implemented in this setup to avoid any issues with part tolerance if required. Thus, the course capacitor values could be reduced in capacitance. It is further understood that, while the exemplified embodiment uses four first capacitors 50 and four second capacitors 70, other numbers of capacitors can be used. Also, other capacitor values can be used.

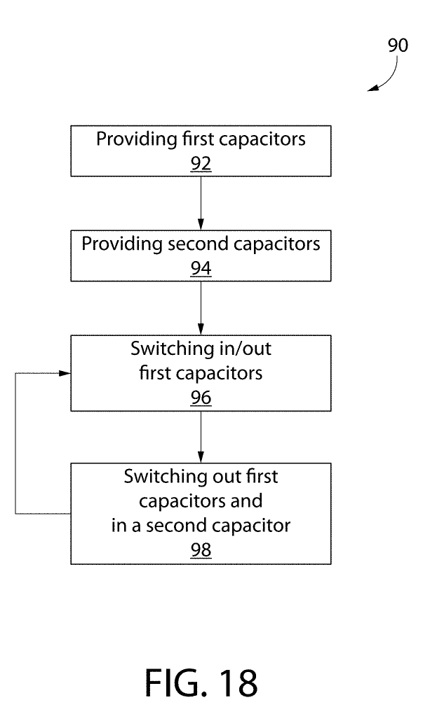

FIG. 18 is a flow chart of a method for varying capacitance according to one embodiment. According to this embodiment, there is provided a plurality of capacitors operably coupled in parallel, the plurality of capacitors comprising first capacitors increasing in capacitance by a factor of about two (operation 92); and second capacitors having substantially the same capacitance (operation 94). The total capacitance can be varied by switching in or out one of the first capacitors and one of the second capacitors. Increasing total capacitance can be provided by switching in and out each of the first capacitors to provide an increasing total capacitance until all of the first capacitors are switched in (operation 96), then switching out the first capacitors and switching in a second capacitor (operation 98). If increasing total capacitance is desired, the system can again switch in and out each of the first capacitors to provide an increasing total capacitance until all of the first capacitors are switched in (operation 98).

It is understood, however, that the EVC does not need to go sequentially through each step, but instead can use software to lookup the next known capacitor position to switch to it directly. It is further understood that a desired total capacitance can be achieved by having switched on a minimal number of capacitors of the plurality of capacitors.

In another embodiment, the variable capacitor can for part of a method of manufacturing a semiconductor, such as the system displayed shown in FIG. 1. The method can include operably coupling a matching network between an RF source and a plasma chamber, the plasma chamber configured to deposit a material layer onto the substrate or etch a material layer from the substrate. The matching network can include an input configured to operably couple to the RF source; an output configured to operably couple to the plasma chamber; and a variable capacitor, the variable capacitor comprising a plurality of capacitors operably coupled in parallel, the plurality of capacitors comprising first capacitors increasing in capacitance by a factor of about two; and second capacitors having substantially the same capacitance. The method can further include the steps of placing a substrate in the plasma chamber; energizing plasma within the plasma chamber by coupling RF power from the RF source into the plasma chamber to perform a deposition or etching; and controlling a total capacitance of the variable capacitor to achieve an impedance match, the total capacitance being controlled by switching in and out capacitors of the plurality of capacitors.

### Heat Pine Inductor

As discussed earlier, several problems can result from inductors becoming heated in high-power systems such as matching networks. Several methods for cooling high temperature inductors can be used, such as forced convection (e.g., fans), increasing thermal mass (e.g., heat sink, fins), and water cooling. Each of these methods, however, has drawbacks. For example, forced convection is limited to the air velocity and flow rate produced by one or more fans, and by the exposed surface area of the inductor. Heat sinks and fins improve temperatures marginally, but are confined to the outside edges of the inductors due to their helical shape. Consequently, the middle of the inductor remains at high temperatures. Running cool water through a hollow pipe inductor can be effective at reducing temperatures throughout the component, but this method requires a water source, which is not available in many high-power RF applications.

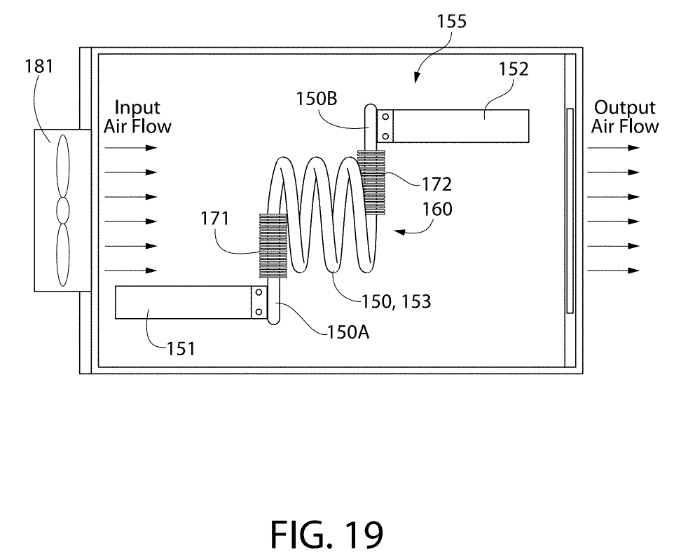

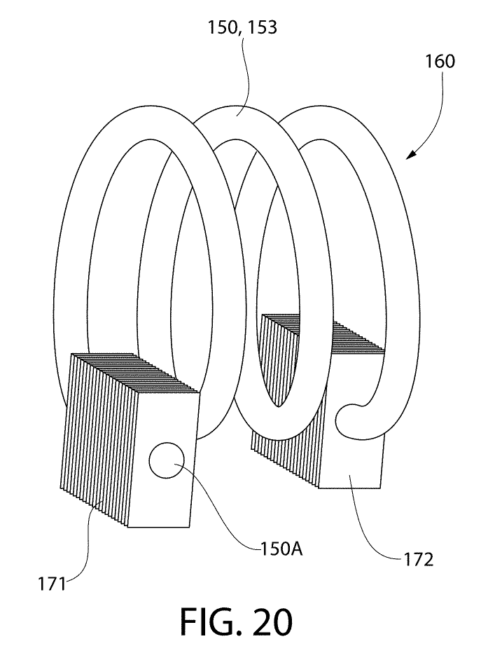

FIG. 19 is a block diagram a portion of a matching network 155 that incorporates a heat pipe inductor 150 according to one embodiment. In this embodiment, the portion of the matching network 155 shown includes two variable capacitors 151, 152. The variable capacitors 151, 152 can be similar to the variable capacitors discussed herein, such as C1 and C2. Further, the matching network can include an input configured to operably couple to an RF source (such as, but not limited to, source 30 discussed herein), and an output configured to operably couple to a load (such as, but not limited to, plasma chamber 20 discussed herein). Electric current travels through the matching network causing a power dissipation creating a loss in the form of heat energy. In the exemplified embodiment, the impedance matching network is positioned between an RF source of at least IkW and a plasma chamber load for manufacturing semiconductor devices, and the power dissipated in the inductor is about 60-80 W. The invention, however, is not so limited to matching networks for semiconductor manufacturing, as the electronic device 160 can be utilized in any type of matching network, or in other high-power systems having one or more heated inductors.

In the exemplified embodiment, an electronic device 160 is positioned between the capacitors 151, 152. The electronic device may comprise the inductor 150 and heat sinks 171, 172. The inductor is formed from a heat pipe 153 that is wound in a three-dimensional shape. The first heat sink 171 may be coupled adjacent to a first end 150A of the heat pipe 153, and the second heat sink 172 may be coupled adjacent to a second end 150B of the heat pipe 153, the second end 150B being opposite to the first end 150A. In a preferred embodiment, liquid in heat pipe is heated to become vapor. This vapor travels to the heat sink, where it cooled and becomes liquid again.

The matching network 155 of claim 1 may further include a fan 181 configured to blow air across the first and second heat sinks to create forced convection and provide further cooling. The fan 181 may also blow air across the inductor 150.

FIG. 20 is a perspective view of the electronic device 160 of FIG. 19. As stated above, the electronic device includes an inductor 150 formed from a heat pipe 153. A first heat sink is coupled adjacent to a first end 150A of the heat pipe 153, and a second heat sink 172 is be coupled adjacent to a second end (not shown) of the heat pipe 153. As can be seen, the heat pipe 153 may be wound into a three-dimensional shape to form an inductor. In other embodiments, the heat pipe may be wound into other three-dimensional shapes to form an inductor. For example, the heat pipe may be wound into the shape of a cone or toroid.

Heat pipes utilize phase transition, in addition to thermal conductivity, to move thermal energy more efficiently than a solid conductor alone. When the ends of the heat pipe inductor are in contact with a heat sink, the resulting maximum temperature is a fraction of a solid pipe or tube inductor, even with minimal air flow.

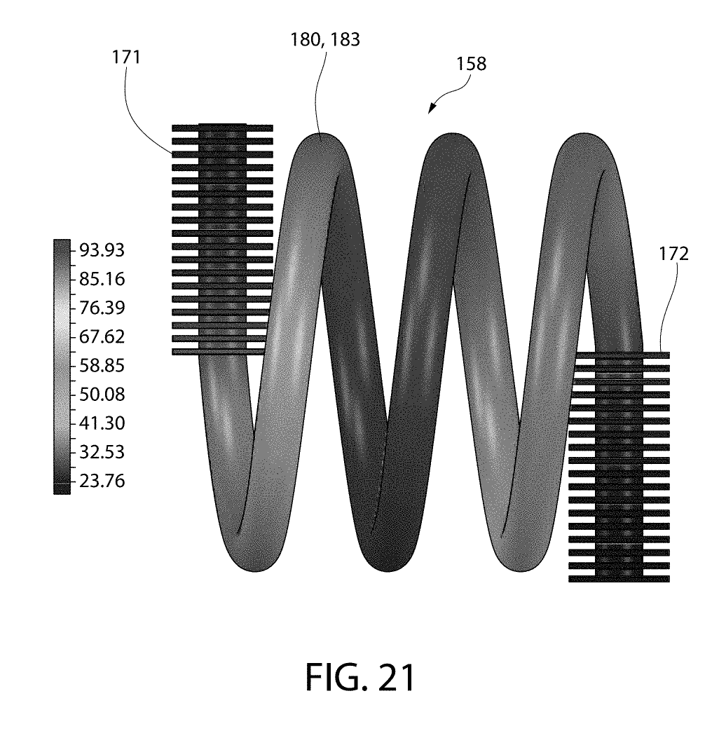

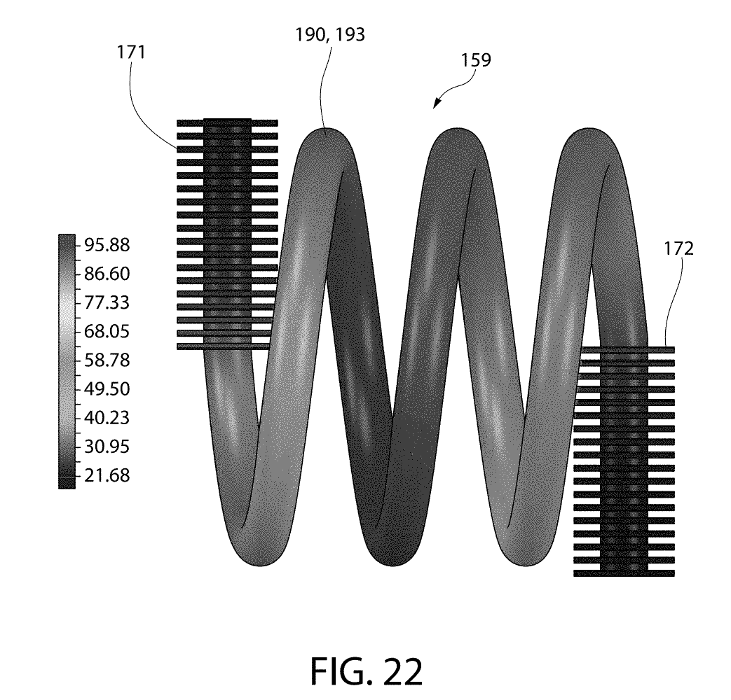

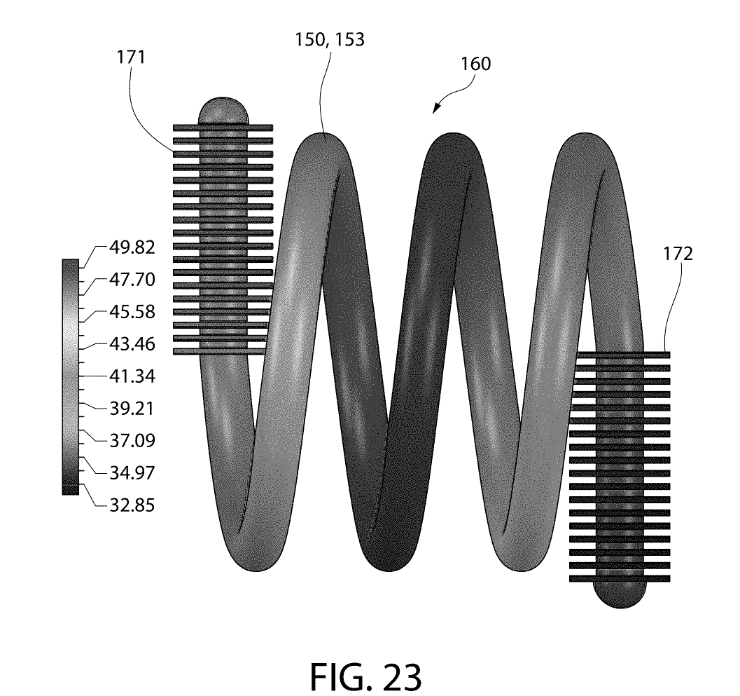

FIGS. 21-23 are temperature surface plots for simulations of heat distribution in a solid copper pipe inductive device (FIG. 21), a copper tube inductive device (FIG. 22), and a heat pipe inductive device (FIG. 23), respectively, according to one embodiment. These simulations were conducted to validate the effective heat transfer of the heat pipe inductive device 160. The computational domain, boundary conditions, and power dissipation are identical across all three simulations. The type of inductor (solid pipe, tube, and heat pipe) is the only parameter altered between simulations.

The simulations were performed inside a 12″×8″×8″ adiabatic box. The box had a 6.5-inch diameter opening where a constant, uniform flow of air moved into the box at 8 m/s. On the other side is a 7″×7″ environmental pressure opening that serves as the outlet condition. The inductor in each simulation received 80 W of power dissipation. The power dissipation is defined as a surface loss, to account for the skin effect. All three inductor variations were given an outer diameter of ⅜ inches. They were wound with three turns at a pitch of 1 inch and center-to-center helical diameter of 3 inches. The ends, or legs, of the inductors had 1.75 inches of extra material where 18 aluminum heat fins (1.5″×0.75″×0.04″) of heat sinks were attached with 0.06-inch spacing between them. This set up can be seen in FIGS. 21-23. It is noted that the invention is not limited to the above specifications, as other design parameters and conditions may be used. For example, while the exemplified inductor 150 has 3 turns, any number of turns can be utilized.

Three simulations were conducted using three different types of ⅜-inch OD copper winding. The results from the simulations can be seen in the temperature surface plots of FIGS. 21-23. The color-coordinated charts show the coils maximum surface temperature (red) and minimum surface temperature (blue). FIG. 21 is an electronic device 158 where the inductor 180 is formed from a solid copper pipe 183. FIG. 22 is an electronic device 159 where the inductor 190 is formed from a copper tubing with a ⅛-inch-thick wall 193. FIG. 23 is an electronic device 160 similar to that shown in FIG. 20, where the inductor 150 is formed from a heat pipe 153. For each of the electronic devices 158, 159, 160, heat sinks 171, 172 are positioned at the ends of the pipe or tube.

As is shown, the heat pipe inductor 150 of FIG. 23 more efficiently transfers its thermal energy to the ends of the pipe where the heat fins then spread the energy across a large surface area exposed to forced convection. While the solid copper pipe inductor 180 has a maximum temperature of 93.93° C., and the copper tubing inductor 190 has a maximum temperature of 95.88° C., the heat pipe inductor 150 has a maximum temperature of only 49.82° C. Further, the heat in the heat pipe inductor 150 is spread more evenly, having a range of 32.85-49.82° C., as opposed to 23.76-93.93° C. for the solid copper pipe inductor 180, and 21.68-95.88° C. for the copper tube inductor 190. The heat pipe inductor 150 provides an inductor whose maximum temperature is 85% cooler than the solid copper pipe inductor 180, and 87% cooler than the copper tube inductor 190.

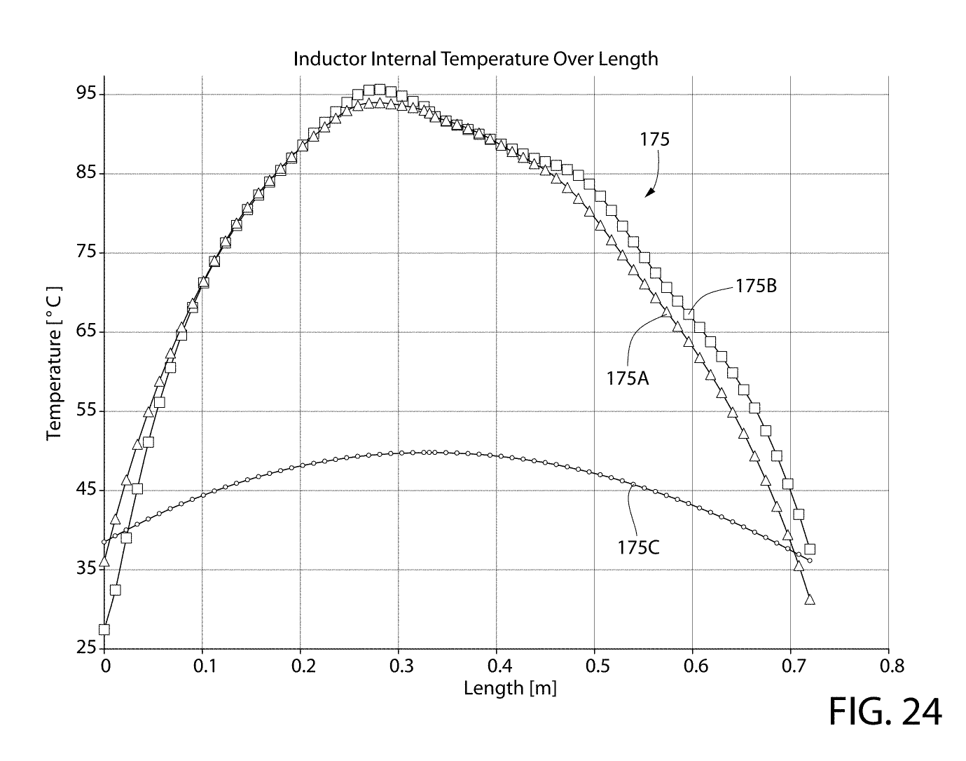

Whiles FIGS. 21-23 indicate outer surface temperatures, FIG. 24 is a graph 175 of the inductor internal temperatures for the simulations of FIGS. 21-23. As can be seen, the graphs indicate internal temperature over the length of the inductor coil, with the inductor being hottest at the middle section of the coil. Three plots are shown, a solid copper pipe plot 175A, a copper tube plot 175B, and a heat pipe plot 175C. As shown, the heat pipe inductor remains significantly cooler that the other inductors. The maximum temperature for the heat pipe plot 175C is over 40° C. lower than the other plots 175A, 175B. Further, the heat pipe inductor's range of temperatures fluctuates to a much lesser extent, having a range of 36.25° C. to 49.8° C. Below is a table showing the inductor internal temperature values over the length of the inductor. It is noted that these internal values are similar to the surface values discussed above.

TABLE 2
Inductor Internal Temperature

| | Heat Pipe | Tube | Solid Pipe |
|---|---|---|---|
| Length [m] | Temp. [° C.] | Temp. [° C.] | Temp. [° C.] |
| 0.00 | 38.5 | 27.4 | 36.1 |
| 0.01 | 39.3 | 32.4 | 41.4 |
| 0.02 | 40.0 | 39.0 | 46.3 |
| 0.03 | 40.7 | 45.2 | 50.8 |
| 0.04 | 41.4 | 51.1 | 55.0 |
| 0.06 | 42.1 | 56.1 | 58.8 |
| 0.07 | 42.7 | 60.5 | 62.4 |
| 0.08 | 43.3 | 64.6 | 65.7 |
| 0.09 | 43.9 | 68.1 | 68.7 |
| 0.10 | 44.4 | 71.2 | 71.4 |
| 0.11 | 44.9 | 73.9 | 74.0 |
| 0.12 | 45.4 | 76.3 | 76.5 |
| 0.13 | 45.9 | 78.5 | 78.8 |
| 0.15 | 46.3 | 80.5 | 80.8 |
| 0.16 | 46.7 | 82.3 | 82.6 |
| 0.17 | 47.1 | 83.9 | 84.2 |
| 0.18 | 47.5 | 85.4 | 85.7 |
| 0.19 | 47.8 | 87.0 | 87.2 |
| 0.20 | 48.2 | 88.6 | 88.5 |
| 0.21 | 48.4 | 90.1 | 89.7 |
| 0.22 | 48.7 | 91.5 | 90.9 |
| 0.24 | 48.9 | 92.8 | 92.0 |
| 0.25 | 49.1 | 94.0 | 93.0 |
| 0.26 | 49.3 | 95.0 | 93.6 |
| 0.27 | 49.4 | 95.5 | 93.9 |
| 0.28 | 49.6 | 95.7 | 94.0 |
| 0.29 | 49.6 | 95.3 | 93.8 |
| 0.30 | 49.7 | 94.8 | 93.6 |
| 0.31 | 49.8 | 94.1 | 93.4 |
| 0.33 | 49.8 | 93.5 | 93.0 |
| 0.33 | 49.8 | 92.8 | 92.7 |
| 0.34 | 49.8 | 92.2 | 92.2 |
| 0.35 | 49.8 | 91.6 | 91.7 |
| 0.36 | 49.7 | 91.1 | 91.2 |
| 0.37 | 49.7 | 90.6 | 90.7 |
| 0.38 | 49.6 | 90.0 | 90.1 |
| 0.39 | 49.4 | 89.4 | 89.4 |
| 0.40 | 49.3 | 88.7 | 88.6 |
| 0.42 | 49.1 | 88.1 | 87.8 |
| 0.43 | 48.9 | 87.5 | 87.1 |
| 0.44 | 48.7 | 86.9 | 86.3 |
| 0.45 | 48.5 | 86.5 | 85.5 |
| 0.46 | 48.3 | 86.1 | 84.5 |
| 0.47 | 48.0 | 85.5 | 83.3 |
| 0.48 | 47.7 | 84.8 | 81.9 |
| 0.49 | 47.3 | 83.7 | 80.3 |
| 0.51 | 47.0 | 82.2 | 78.5 |
| 0.52 | 46.6 | 80.4 | 76.7 |
| 0.53 | 46.2 | 78.4 | 74.8 |
| 0.54 | 45.8 | 76.4 | 72.9 |
| 0.55 | 45.3 | 74.4 | 71.1 |
| 0.56 | 44.8 | 72.5 | 69.4 |
| 0.57 | 44.4 | 70.6 | 67.6 |
| 0.58 | 43.9 | 68.9 | 65.7 |
| 0.60 | 43.3 | 67.3 | 63.8 |
| 0.61 | 42.8 | 65.6 | 61.8 |
| 0.62 | 42.2 | 63.8 | 59.6 |
| 0.63 | 41.6 | 61.9 | 57.4 |
| 0.64 | 41.0 | 59.9 | 54.9 |
| 0.65 | 40.4 | 57.7 | 52.2 |
| 0.66 | 39.7 | 55.4 | 49.4 |
| 0.67 | 39.0 | 52.6 | 46.3 |
| 0.69 | 38.4 | 49.4 | 43.0 |
| 0.70 | 37.6 | 45.8 | 39.4 |
| 0.71 | 36.9 | 42.0 | 35.5 |
| 0.72 | 36.2 | 37.6 | 31.3 |

For a given application, the heat pipe design (e.g., diameter, length, and working fluid) is driven by the specific amount of power that needs to be moved. Generally, larger-diameter pipes can move more heat. High-power application will favor larger-diameter pipes, and inductor shapes that allow larger-diameter pipes, such as the cylinder shape shown in the above discussed embodiments. A shape that required small, thin wire would not be ideal for a high-power application. Further, heat pipes have limits on how much heat they can move. If the power dissipation in the inductor is too great for the selected heat pipe, it will reach a critical point where the gas inside is not able to condense, making the heat pipe non-functional. The type of heat sink used would also be dependent upon the amount of power dissipated through the inductor. For example, as power dissipation increases, fins on the sink may increase in size and/or quantity.

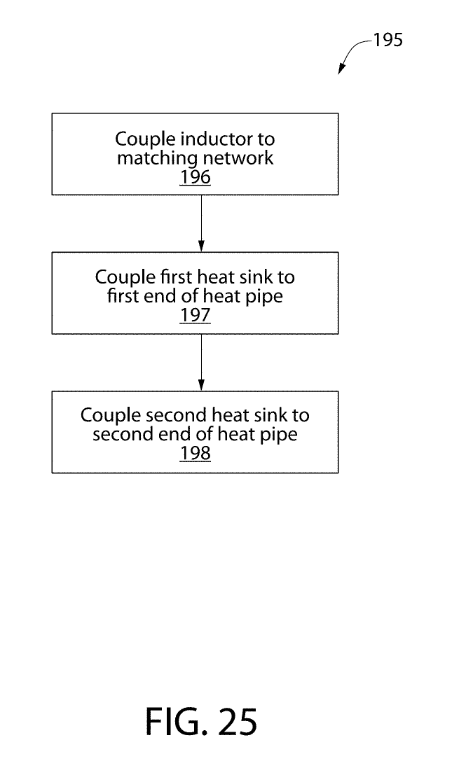

FIG. 25 is a flow chart of a method 195 for cooling an impedance matching network according to one embodiment. In this embodiment, an inductor is coupled to the matching network, the inductor formed from a heat pipe that is wound in a three-dimensional shape (operation 196). Further, a first heat sink to a first end of the heat pipe (operation 197), and a second heat sink is coupled to a second, opposite end of the heat pipe (operation 198). Use of this heat pipe inductor with heat sinks enables improved cooling of the inductor, and thus of the matching network.

As discussed, a matching network utilizing such a heat pipe inductor can be utilized in a system or method for manufacturing of semiconductors. According to such a method, a matching network may be operably coupled between an RF source and a plasma chamber, the plasma chamber configured to deposit a material layer onto the substrate or etch a material layer from the substrate. The matching network may include an input configured to operably couple to the RF source, an output configured to operably couple to the plasma chamber, a first variable capacitor, an inductor formed from a heat pipe that is wound in a three-dimensional shape, a first heat sink coupled adjacent to a first end of the heat pipe, and a second heat sink coupled adjacent to a second, opposite end of the heat pipe. A substrate may be placed in the plasma chamber, and the plasma may be energized within the plasma chamber by coupling RF power from the RF source into the plasma chamber to perform a deposition or etching. The capacitance of the first variable capacitor may be controlled to achieve an impedance match. While the above embodiments discuss using one or more variable capacitors in a matching network to achieve an impedance match, it is noted that any variable reactance element can be used. A variable reactance element can include one or more reactance elements, where a reactance element is a capacitor or inductor or similar reactive device.

The embodiments discussed herein provide many advantages. As shown by the foregoing simulations, the heat pipe inductor provides dramatic cooling improvements. The disclosed embodiments can provide improved cooling performance while saving space, which is valuable in matching networks for semiconductor manufacturing, as well as certain other high-power applications. Further, the heat pipe inductor is particularly useful in cooling the middle portions of the inductor, without requiring other resources such as a regular water source.

As used throughout, ranges are used as shorthand for describing each and every value that is within the range. Any value within the range can be selected as the terminus of the range. In addition, all references cited herein are hereby incorporated by referenced in their entireties. In the event of a conflict in a definition in the present disclosure and that of a cited reference, the present disclosure controls.

While the invention or inventions have been described with respect to specific examples, those skilled in the art will appreciate that there are numerous variations and permutations of the above described invention(s). It is to be understood that other embodiments may be utilized and structural and functional modifications may be made without departing from the scope of the present invention(s). Thus, the spirit and scope should be construed broadly as set forth in the appended claims.

What is claimed is:

1. An impedance matching network comprising:
an input configured to operably couple to a radio frequency (RF) source;
an output configured to operably couple to a load;
a first variable capacitor;
an inductor formed from a heat pipe that is wound in a three-dimensional shape;
a first heat sink coupled adjacent to a first end of the heat pipe; and
a second heat sink coupled adjacent to a second, opposite end of the beat pipe.

2. The matching network of claim 1 wherein the heat pipe is wound in the shape of a cylinder.

3. The matching network of claim 1 further comprising a fan configured to blow air across the first and second heat sinks.

4. The matching network of claim 1 wherein the load is a plasma chamber.

5. The matching network of claim 1 wherein the RF source provides a power of at least 1 kW.

6. The matching network of claim 1 further comprising a second variable capacitor.

7. The matching network of claim 6 further comprising a third capacitor in series with the second variable capacitor.

8. The matching network of claim 7 wherein the third capacitor is a non-variable capacitor.

9. The matching network of claim 8 wherein:
the first variable capacitor forms part of a first shunt parallel to the RF source;
the second variable capacitor forms part of a second shunt parallel to the load; and
the second shunt comprises the third capacitor.

10. A method of cooling an impedance matching network, the method comprising:
coupling an inductor to the matching network, the inductor formed from a heat pipe that is wound in a three-dimensional shape;
coupling a first heat sink to a first end of the heat pipe; and
coupling a second heat sink to a second, opposite end of the heat pipe.

11. The method of claim 10 wherein the heat pipe is wound in the shape of a cylinder.

12. The method of claim 10 further comprising blowing air across the first and second heat sinks.

13. The method of claim 10 wherein the matching network is operably coupled to a radio frequency (RF) source and a plasma chamber.

14. The method of claim 13 wherein the RF source provides a power of at least 1 kW.

15. A method of manufacturing a semiconductor comprising:
operably coupling a matching network between an RF source and a plasma chamber, the plasma chamber configured to deposit a material layer onto the substrate or etch a material layer from the substrate, and the matching network comprising:
an input configured to operably couple to the RF source;
an output configured to operably couple to the plasma chamber;
a first variable capacitor;
an inductor formed from a heat pipe that is wound in a three-dimensional shape;
a first heat sink coupled adjacent to a first end of the heat pipe; and
a second heat sink coupled adjacent to a second, opposite end of the heat pipe;
placing a substrate in the plasma chamber;
energizing plasma within the plasma chamber by coupling RF power from the RF source into the plasma chamber to perform a deposition or etching; and
controlling a capacitance of the first variable capacitor to achieve an impedance match.

16. An electronic device comprising:
an inductor formed from a heat pipe that is wound in a three-dimensional shape;
a first heat sink coupled adjacent to a first end of the heat pipe; and
a second heat sink coupled adjacent to a second, opposite end of the heat pipe.

17. The electronic device of claim 16 wherein the heat pipe is wound in the shape of a cylinder.

18. The electronic device of claim 16 wherein the inductor has three turns.

19. The electronic device of claim 16 wherein the inductor is configured to connect to a first variable capacitor and a second variable capacitor.

20. The electronic device of claim 16 wherein the first and second heat sinks comprise aluminum heat fins.
